(19) United States
(12) Patent Application Publication
(10) Pub. No.: US 2005/0161781 A1
(43) Pub. Date: Jul. 28, 2005

(54) HYBRID INTEGRATED CIRCUIT DEVICE AND MANUFACTURING METHOD THEREOF

(75) Inventor: Masaru Kanakubo, Gunma (JP)

Correspondence Address: WATCHSTONE P + D, 1300 EYE STREET, NW, SUITE 400 EAST, WASHINGTON, DC, 20005, US

(73) Assignees: SANYO ELECTRIC CO., LTD., Osaka (JP); KANTO SANYO SEMICONDUCTORS CO., LTD., Gunma (JP)

(21) Appl. No.: 10/905,245

(22) Filed: Dec. 22, 2004

(30) Foreign Application Priority Data
Dec. 24, 2003 (JP) 2003-428411

(51) Int. Cl. H01L 29/47

(52) U.S. Cl. 257/678

(57) ABSTRACT

Disclosed are a hybrid integrated circuit device and a method of manufacturing thereof which can enhance reliability of connections between conductive patterns and a circuit board. A method of manufacturing the hybrid integrated circuit device comprises the steps of providing an insulating layer on a surface of the circuit board made of metal, forming conductive patterns on the surface of the insulating layer so as to constitute a plurality of units, forming exposure holes so as to penetrate the insulating layer in the respective units and thereby to expose the circuit board from bottom portions of the exposure holes, forming flat portions at the bottom portions of the exposure holes in the respective units, electrically connecting circuit elements to the conductive patterns in the respective units, electrically connecting the flat portions to the conductive patterns in the respective units by use of thin metallic wires, and separating the respective units.

### CROSS-REFERENCE TO RELATED APPLICATIONS

Priority is claimed to Japanese Patent Application Number JP2003-428411 filed on Dec. 24, 2003, the disclosure of which is incorporated herein by reference in its entirety.

### FIELD OF THE INVENTION

The present invention relates to a hybrid integrated circuit device and a manufacturing method thereof, more specifically to a hybrid integrated circuit device having a region for electrically connecting a conductive pattern to a circuit board and a manufacturing method thereof.

### DESCRIPTION OF THE RELATED ART

A configuration of a conventional hybrid integrated circuit device will be described with reference to FIGS. 12A to 12C (see Patent Document 1, for example). FIG. 12A is a perspective view of a hybrid integrated circuit device 100, and FIG. 12B is a cross-sectional view taken along the X-X′ line in FIG. 12A. FIG. 12C is an enlarged cross-sectional view showing a portion where a conductive pattern 108 is electrically connected to a board 106.

The conventional hybrid integrated circuit device 100 has the following configuration. The hybrid integrated circuit device 100 includes the rectangular board 106, the conductive pattern 108 formed on an insulating layer 107 provided on a surface of the board 106, circuit elements 104 fixed onto the conductive pattern 108, metallic wires 105 for electrically connecting the circuit elements 104 to the conductive pattern 108, and leads 101 electrically connected to the conductive pattern 108. All the above-described constituents of the hybrid integrated circuit device 100 are sealed by sealing resin 102. The sealing method using the sealing resin 102 includes injection molding applying thermoplastic resin and transfer molding applying thermosetting resin. In addition, the constituents may be sealed while exposing a rear surface of the board to outside.

A configuration of the portion where the conductive pattern 108 is connected to the board 106 will be described with reference to FIG. 12C. The conductive pattern 108 is connected to the board 106 by connecting a bottom portion of an exposed portion 110 to the conductive pattern 108 with the thin metallic wire 105. By electrically connecting the board 106 to the conductive pattern 108 as described above, it is possible to approximate potential values of the both constituents and thereby to suppress adverse effects attributable to parasitic capacitance.

The exposed portion 110 is a hole region pierced through the insulating layer 107 to expose the board 106. As the exposed portion 110 is formed by use of a drill, the bottom portion is formed into a rough surface. Accordingly, the thin metallic wire 105 generally called a heavy line having a diameter of about 200 μm is used to ensure adhesion of the thin metallic wire 105 to the exposed portion 110.

(Patent Document 1) Japanese Unexamined Patent Publication No. 6(1994)-177295 (page 4, FIG. 1)

However, the above-described hybrid integrated circuit device and the manufacturing method thereof have the following problems.

Specifically, since the bottom portion of the exposed portion 110 is formed into the rough surface, adhesion between this bottom portion and the thin metallic wire 105 may be insufficient and reliability of connection between the both constituent may be degraded.

Moreover, when the above-described heavy line is used as the thin metallic wire 105, the heavy thin metallic wire is less flexible and may therefore occupy a large area for forming the thin metallic wire 105. To be more precise, as shown in FIG. 12C, a distance between from a junction of the thin metallic wire 105 and the exposed portion 110 to a junction of the thin metallic wire 105 and the conductive pattern 108 becomes long. Therefore, a region used for connection of the thin metallic wire 105 includes a dead space, which may hinder miniaturization of circuit designs.

In addition, when the heavy line is used as the thin metallic wire 105 for connecting the exposed portion 110 to the conductive pattern 108, a large bonder is required to perform die bonding of the heavy line. Meanwhile, the circuit elements 104 are also connected by use of the thin metallic lines 105. Here, the circuit elements 104 may be connected by use of fine thin metallic wires having diameters of about 40 μm for configuring an electric circuit having a small output. In such a case, the large bonder is required solely for connecting the exposed portion 110 and the conductive pattern 108, which leads to an increase in manufacturing costs.

### SUMMARY OF THE INVENTION

The present invention has been made in consideration of the foregoing problems. The present invention provides a hybrid integrated circuit device and a manufacturing method thereof, which are capable of improving reliability of a junction of a conductive pattern and a circuit board.

A hybrid integrated circuit device of the present invention includes a circuit board made of metal, an insulating layer covering a surface of the circuit board, a conductive pattern formed on a surface of the insulating layer, a circuit element disposed in and electrically connected to a desired position of the conductive pattern, an exposure hole penetrating the insulating layer and exposing the circuit board, a flat portion formed on a bottom portion of the exposure hole, and a thin metallic wire for electrically connecting the flat portion to the conductive pattern.

A method of manufacturing a hybrid integrated circuit device of the present invention includes the steps of providing an insulating layer on a surface of a circuit board made of metal, forming a conductive pattern on a surface of the insulating layer, forming an exposure hole so as to penetrate the insulating layer and thereby to expose the circuit board from a bottom portion of the exposure hole, forming a flat portion at the bottom portion of the exposure hole, electrically connecting a circuit element to the conductive pattern, and electrically connecting the flat portion to the conductive pattern by use of a thin metallic wire.

Moreover, another method of manufacturing a hybrid integrated circuit device of the present invention includes the steps of providing an insulating layer on a surface of a circuit board made of metal, forming conductive patterns on the surface of the insulating layer so as to constitute a plurality of units, forming exposure holes so as to penetrate the insulating layer in the respective units and thereby to expose the circuit board from bottom portions of the exposure holes, forming flat portions at the bottom portions of the exposure holes in the respective units, electrically connecting circuit elements to the conductive patterns in the respective units, electrically connecting the flat portions to the conductive patterns in the respective units by use of thin metallic wires, and separating the respective units.

According to the hybrid integrated circuit device and its manufacturing method of the present invention, by forming the flat portion at the bottom portion of the exposed portion configured to expose the circuit board, it is possible to connect the circuit board to the conductive pattern by use of fine thin metallic wires having diameters of about 40 μm. Therefore, it is possible to reduce an area required for connecting the circuit board to the conductive pattern, and thereby to downsize the entire device. Moreover, when using the fine thin metallic wires also for connecting the circuit element, it is possible to achieve a manufacturing process by applying only a bonder suitable for the fine thin metallic wires.

In addition, as the thin metallic wire is connected to the flat portion after flattening the bottom portion of the exposed portion, it is possible to improve reliability of connection between the exposed portion and the thin metallic wire.

### BRIEF DESCRIPTION OF THE DRAWINGS

FIG. 1A is a perspective view and FIG. 1B is a cross-sectional view showing a hybrid integrated circuit device of the present invention.

FIG. 2A is another perspective view and FIG. 2B is another cross-sectional view showing the hybrid integrated circuit device of the present invention.

FIG. 3A is a plan view, FIG. 3B is a cross-sectional view, and FIG. 3C is an enlarged view showing a method of manufacturing a hybrid integrated circuit device of the present invention.

FIG. 4A is another cross-sectional view and FIG. 4B is still another cross-sectional view showing the method of manufacturing a hybrid integrated circuit device of the present invention.

FIG. 5A is another plan view, FIG. 5B is another perspective view, and FIG. 5C is another enlarged view showing the method of manufacturing a hybrid integrated circuit device of the present invention.

FIG. 6A is another perspective view and FIG. 6B is another cross-sectional view showing the method of manufacturing a hybrid integrated circuit device of the present invention.

FIG. 7A is another cross-sectional view and FIG. 7B is still another cross-sectional view showing the method of manufacturing a hybrid integrated circuit device of the present invention.

FIG. 8 is another plan view showing the method of manufacturing a hybrid integrated circuit device of the present invention.

FIG. 9 is another cross-sectional view showing the method of manufacturing a hybrid integrated circuit device of the present invention.

FIG. 10A is another perspective view and FIG. 10B is another cross-sectional view showing the method of manufacturing a hybrid integrated circuit device of the present invention.

FIG. 11 is another cross-sectional view showing the method of manufacturing a hybrid integrated circuit device of the present invention.

FIG. 12A is a perspective view, FIG. 12B is a cross-sectional view, and FIG. 21C is an enlarged cross-sectional view showing a conventional hybrid integrated circuit device.

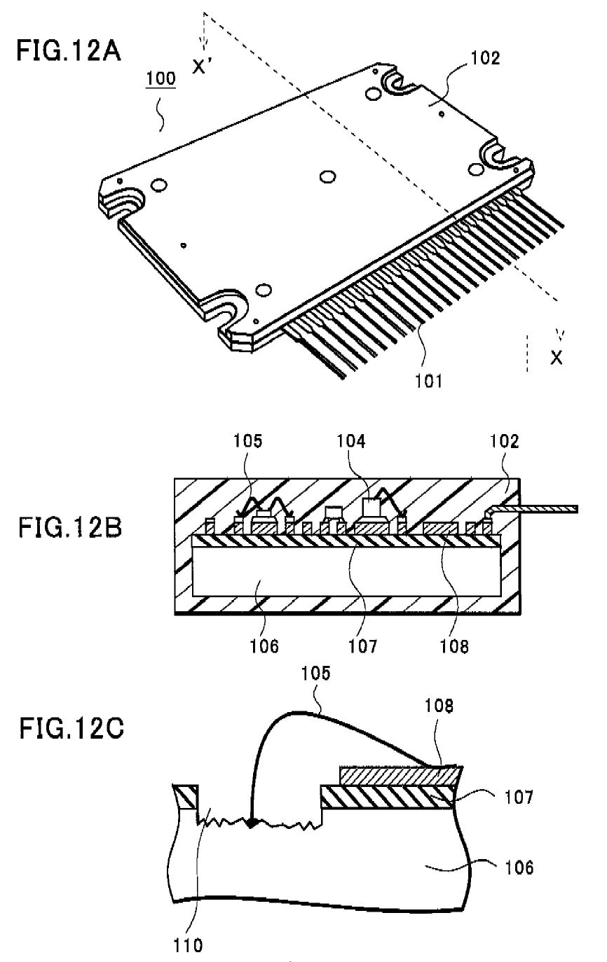

### DETAILED DESCRIPTION OF THE PREFERRED EMBODIMENT

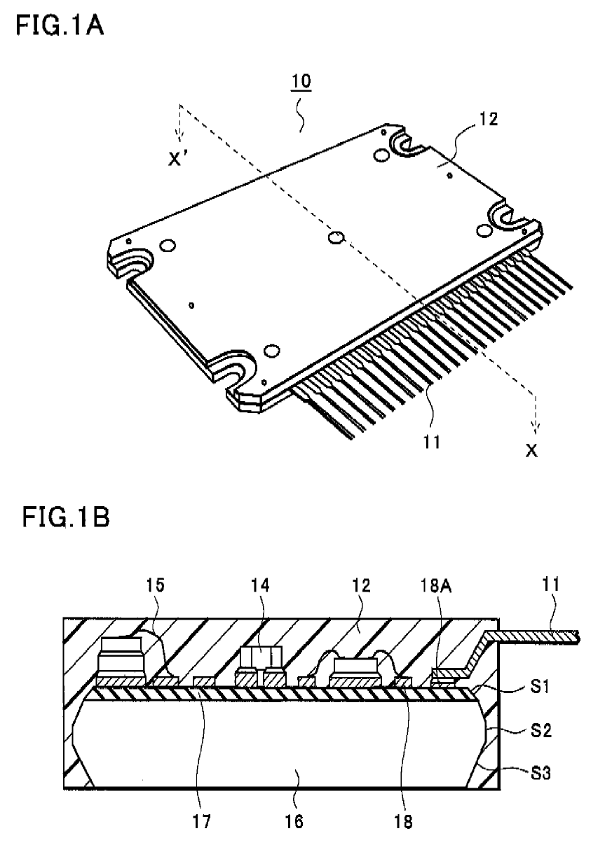

A configuration of a hybrid integrated circuit device 10 according to a preferred embodiment of the present invention will be described with reference to FIGS. 1A and 1B. FIG. 1A is a perspective view of the hybrid integrated circuit device 10, and FIG. 1B is a cross-sectional view taken along the X-X′ line in FIG. 1A.

The hybrid integrated circuit device 10 of the preferred embodiment includes a circuit board 16 having an electric circuit composed of a conductive pattern 18 and circuit elements 14 formed on a surface thereof, and sealing resin 12 for sealing the electric circuit and covering at least the surface of the circuit board 16. The respective constituents will now be described below.

The circuit board 16 is a board made of metal such as aluminum or copper. For example, when a board made of aluminum is adopted as the circuit board 16, there are two methods of insulating the circuit board 16 from the conductive pattern 18 formed on the surface thereof. The first method is to subject the surface of the aluminum board to an alumite treatment. The second method is to form an insulating layer 17 on the surface of the aluminum board and then to form the conductive pattern 18 on a surface of the insulating film 17. Here, in order to release heat generated by the circuit elements 14 placed on the surface of the circuit board 16 effectively to outside, a rear surface of the circuit board 16 is exposed from the sealing resin 12 to outside. Alternatively, it is also possible to seal the entire device including the rear surface of the circuit board 16 by use of the sealing resin 12 to improve moisture resistance of the entire device.

The circuit elements 14 are fixed onto the conductive pattern 18, whereby the circuit elements 14 and the conductive pattern 18 collectively constitute a given electric circuit. Active elements such as transistors or diodes, and passive elements such as capacitors or resistors are adopted as the circuit elements 14. Meanwhile, an element causing a large amount of heat generation such as a semiconductor element for a power system may be fixed to the circuit board 16 through a heat sink made of metal. Here, active elements and the like mounted face up thereon are electrically connected to the conductive pattern 18 through thin metallic wires 15.

The conductive pattern 18 is made of metal such as copper, and is formed so as to be insulated from the circuit board 16. Moreover, pads 18A made of the conductive pattern 18 are formed on an edge where leads 11 are drawn out. Here, a plurality of pads 18A are aligned in the vicinity of an edge of the circuit board 16. In addition, the conductive pattern 18 is adhered to the surface of the circuit board 16 through the insulating layer 17 as adhesive.

The insulating layer 17 is formed so as to cover the surface of the circuit board 16, in which a resin material such as epoxy resin is filled with high density of filler such as alumina. Heat resistance of the insulating layer 17 is reduced by the filler filled therein.

The leads 11 are fixed to the pads 18A provided at a peripheral portion of the circuit board 16, and have a function to perform input and output to and from outside. Here, multiple leads 11 are provided on one edge. Adhesion between the leads 11 and the pads 18A is achieved by use of a conductive adhesive such as solder (a solder material). Alternatively, it is possible to provide the pads 18A on an opposite edge of the circuit board 16 and to fix the leads 11 to these pads.

The sealing resin 12 is formed by transfer molding using thermosetting resin or by injection molding using thermoplastic resin. Here, the sealing resin 12 is formed so as to seal the circuit board 16 and the electric circuit formed on the surface thereof, while the rear surface of the circuit board 16 is exposed out of the sealing resin 12.

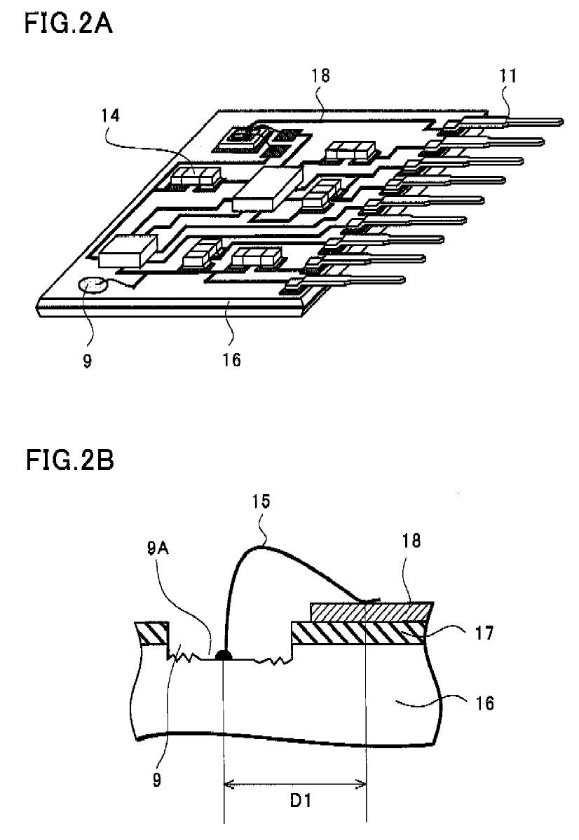

A configuration of a junction of the conductive pattern 18 formed on the surface of the circuit board 16 and the circuit board 16 will be described with reference to FIGS. 2A and 2B. FIG. 2A is a perspective view of the hybrid integrated circuit device when omitting the sealing resin 12. FIG. 2B is an enlarged cross-sectional view of the junction of the conductive pattern 18 and the circuit board 16.

As shown in FIG. 2A, the conductive pattern 18, which is insulated from the circuit board 16 through the insulating layer 17, is formed on the surface of the circuit board 16. The given electric circuit is formed by disposing the circuit elements 14 in desired positions on the conductive pattern 18. Moreover, in order to suppress generation of parasitic capacitance between the conductive pattern 18 and the circuit board interposing the insulating layer 17, the conductive pattern 18 and the circuit board 16 are electrically connected to each other. By connecting the both constituents as described above, it is possible to approximate electric potential of the conductive pattern 18 to electric potential of the circuit board 16, and thereby to reduce the parasitic capacitance. As for the conductive pattern 18 to be connected to the circuit board 16, it is possible to adopt the conductive pattern 18 which is connected to the ground potential, for example. In this way, it is possible to approximate the electric potential of the conductive pattern 18 to the ground potential. Here, the circuit board 16 is electrically connected to the conductive pattern 18 through an exposure hole 9 partially exposing the circuit board 16. Although only one exposure hole 9 is provided on the circuit board 16 in FIG. 2A, it is also possible to form a plurality of exposure holes 9.

A configuration in the vicinity of the exposure hole 9 will be described with reference to FIG. 2B. The exposure hole 9 is a hole configured to expose the circuit board 16 partially by penetrating the insulating layer 17. The depth of the exposure hole 9 is deeper than the thickness of the insulating layer 17 so as to expose the circuit board 16. When the exposure hole 9 is formed by use of a drill, a bottom portion of the exposure hole 9 is formed into a rough surface. Further, a flat portion 9A is formed partially on the bottom portion of the exposure hole 9. The flat portion 9A is formed at least flatly enough to connect the thin metallic wire 15 (hereinafter referred to as a thin wire) having a diameter of about 40 μm with sufficient connection strength. Alternatively, it is also possible to use a thin wire which is similar to the one for connecting the circuit elements 14 as the thin metallic wire 15 for connecting the exposure hole 9. In this way, it is possible to perform wire bonding of the entire device by use of the single type of thin metallic wire 15. Here, the flat portion 9A is formed by partially flattering only the vicinity of a central portion at the bottom portion of the exposure hole. However, it is also possible to form the entire bottom portion of the exposure hole 9 flatly.

As shown in FIG. 2B, it is possible to shorten a distance D1 from a junction of the thin metallic wire 15 and the exposure hole 9 to a junction of the thin metallic wire 15 and the conductive pattern 18 in this embodiment. Conventionally, the distance D1 needs to be about 3 mm or more because a heavy line having a diameter of about 200 μm is used. In this embodiment, since connection is achieved by use of the thin wire having the diameter of about 40 μm, it is possible to set the distance D1 equal to or below 1 mm. Such reduction also contributes to downsizing of the entire device.

In addition, by using the same material for the thin metallic wire 15 and for the circuit board 16, it is possible to perform wire bonding while omitting a configuration of a plated film for improving bondability. For example, it is possible to adopt metal mainly containing aluminum as the material for the thin metallic wire 15 and for the circuit board 16.

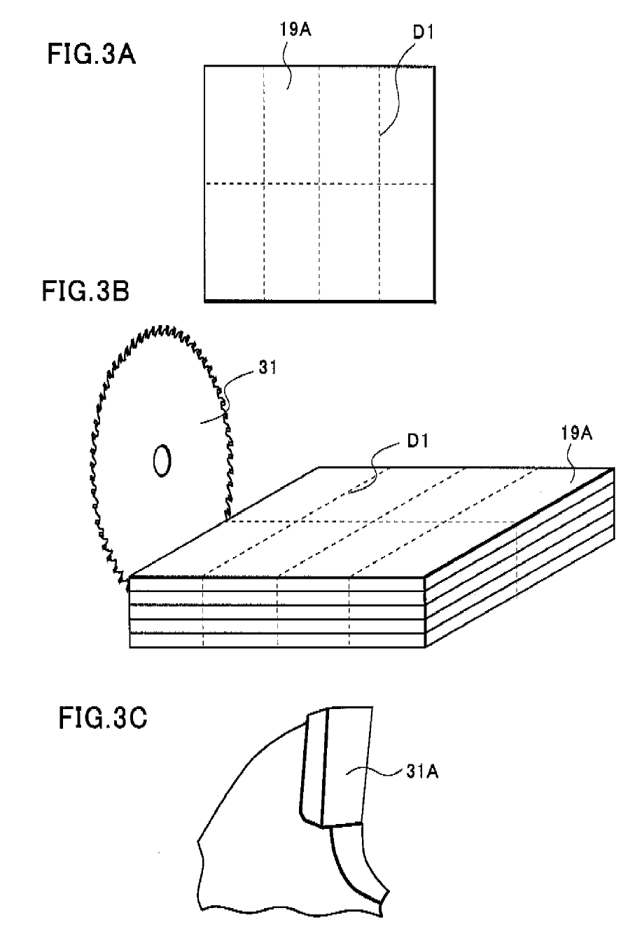

A method of manufacturing the hybrid integrated circuit device will be described with reference to FIG. 3A to FIG. 11. The method of manufacturing the hybrid integrated circuit device of the preferred embodiment includes the steps of providing an insulating layer 17 on the surface of the board made of metal, forming a conductive patterns 18 on the surface of the insulating layer 17 so as to constitute a plurality of units 32, forming exposure holes 9 so as to penetrate the insulating layer 17 in respective units 32 and thereby to expose a circuit board 16 from the bottom portions of the exposure holes 9, forming flat portions 9A at the bottom portions of the exposure holes 9 in the respective units, electrically connecting circuit elements 14 to the conductive patterns 18 in the respective units 32, electrically connecting the flat portions to the conductive patterns in the respective units by use of the thin metallic wires, and separating the respective units 32. The respective steps mentioned above will be described below in detail.

First process: see FIGS. 3A to 3C

This is a process for forming medium-sized metal boards 19B by dividing a large-sized metal board 19A.

Firstly, as shown in FIG. 3A, the large-sized metal board 19A is prepared. For example, the large-sized metal board 19A has the dimension of approximately one meter square. Here, the metal board 19A is an aluminum plate with both surfaces subjected to an alumite treatment. Further, an insulating layer is provided on a surface of the metal board 19A. Moreover, copper foil for forming the conductive pattern is attached to a surface of the insulating layer.

Next, as shown in FIG. 3B, the metal board 19A is divided along dicing lines D1 by use of a cutting saw 31. Here, multiple sheets of stacked metal boards 19A are divided at the same time. The cutting saw 31 divide the metal boards 19A along the dicing lines D1 while rotating at high speed. To be more precise, the large-sized metal board 19A having the square shape is divided into eight pieces along the dicing lines D1, thereby forming the medium-sized metal boards 19B of a rectangular shape. Here, the medium-sized metal board 19B is formed into the shape in which a long edge is twice as long as a short edge.

The shape and other features of the cutting saw 31 will be described with reference to FIG. 3C. FIG. 3C is an enlarged view showing the vicinity of a blade 31A of the cutting saw 31. An end portion of the blade 31A is formed into a flat shape, and diamond particles are fused therein. By rotating the cutting saw provided with the above-described blade at high speed, it is possible to divide the metal board 19A along the dicing lines D1.

The medium-sized metal board 19B manufactured in this step is subjected to etching to remove the copper foil partially, thereby forming the conductive patterns 18. The number of the conductive patterns 18 formed herein vary depending on the size of the metal board 19B and the size of the hybrid integrated circuit. However, it is possible to form the conductive patterns sufficient for forming several tens or several hundreds of the hybrid integrated circuits on each metal board 19B.

Moreover, the units composed of the conductive patterns 18 are formed in a matrix on the singles metal board 19A in this case. Here, the unit means a unit for constituting one hybrid integrated circuit device.

Here, it is also possible to divide the metal plate 19A by stamping. To be more precise, it is possible to form the metal boards 19B each having the size corresponding to several pieces (2 to 8 pieces, for example) of the circuit boards by means of stamping.

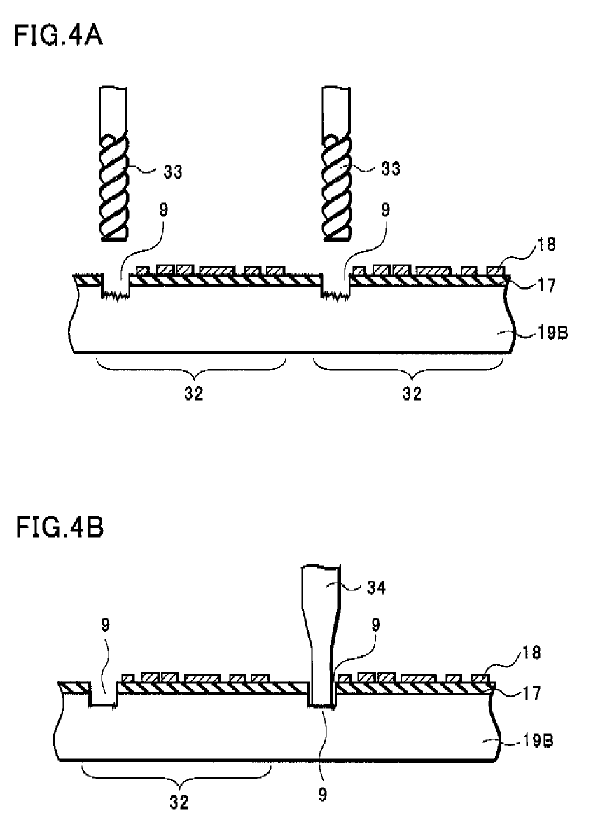

Second process: see FIGS. 4A and 4B

This is a process for forming the exposure holes 9 in the respective units 32 of the metal board 19B and forming the flat portions 9A at the bottom portions of the exposure holes 9.

Firstly, as shown in FIG. 4A, the exposure holes 9 are formed in the respective units 32 of the metal board 19B. The exposure holes 9 can be formed by use of a drill 33 (an end mill) having a tip end formed into a flat shape. The exposure holes 9 are formed by rotating this drill 33 at high speed. When the metal mainly containing aluminum is used as the material for the metal board 19A, the bottom portions of the exposure holes 9 are formed into rough surfaces because aluminum is “viscous” metal. Moreover, the insulating layer 17 is penetrated by forming the exposure holes 9.

The insulating layer 17 is extremely hard because the insulating layer 17 contains inorganic filler such as alumina. Accordingly, the drill 33 is worn away very quickly in the course of forming the exposure holes 9. Such wear is more significant when the diameter of the drill 33 used is smaller. Therefore, in light of mass productivity, it is preferable to use a thicker drill 33. On the contrary, in light of downsizing the circuit board 16, it is preferable to reduce the diameter of the drill 33 and thereby to reduce the area occupied by the exposure hole 9. Accordingly, it is preferable to form the exposure holes 9 by use of the drill 33 having the diameter of about 1 mm. This diameter is appropriate for reducing the area occupied by the exposure hole 9 and for improving productivity by minimizing the wear of the drill 33 at the same time. Moreover, in this process, the exposure holes 9 are formed in the respective units 32 formed in a matrix.

Furthermore, in the course of forming the exposure holes 9 by use of the drill 33, the insulating layer 17 formed on the surface of the circuit boards 16 also has an advantage of facilitating a cutting work. To be more precise, as the insulating layer 17 is placed as an upper layer of the circuit boards 16, it is possible to reduce of cutting burr which is generated when cutting the circuit boards 16 made of metal.

As shown in FIG. 4B, the flat portions 9A are formed at the bottom portions of the exposure holes 9 formed in the previous step. Various methods are conceivable as the method of forming the flat portions 9A. For example, it is possible to flatten the bottom portion of the exposure hole 9 by heating. Meanwhile, it is also possible to form the flat portion 9A by chemically melting the bottom portion of the exposure hole 9. Moreover, it is also possible to form the flat portion 9A by forming a plated film on the bottom portion of the exposure hole 9. Furthermore, it is also possible to attach an abutting bar 34, which has a tip end formed into a flat shape, onto the bottom portion of the exposure hole 9.

FIG. 4B shows the method using the abutting bar 34. The tip end of the abutting bar 34 has a flat surface, and the diameter thereof is formed equal to or below the diameter of the exposure hole 9. The flat portion 9A is formed by attaching the tip end of the abutting bar 34 onto the bottom portion of the exposure hole 9. It is possible to set the flatness of the flat portion 9A to approximately the same level as nickel plating and the like. Meanwhile, the strength of the abutting bar 34 pressing against the bottom portion of the exposure hole 9 is adjusted appropriately so as not to form a stamp on a rear surface of the metal board 19B. Meanwhile, the flat portion 9A having the diameter of about 0.2 mm or above is required for wire bonding. Accordingly, the tip end of the abutting bar 34 is also formed into the size having diameter equal to 0.2 mm or above.

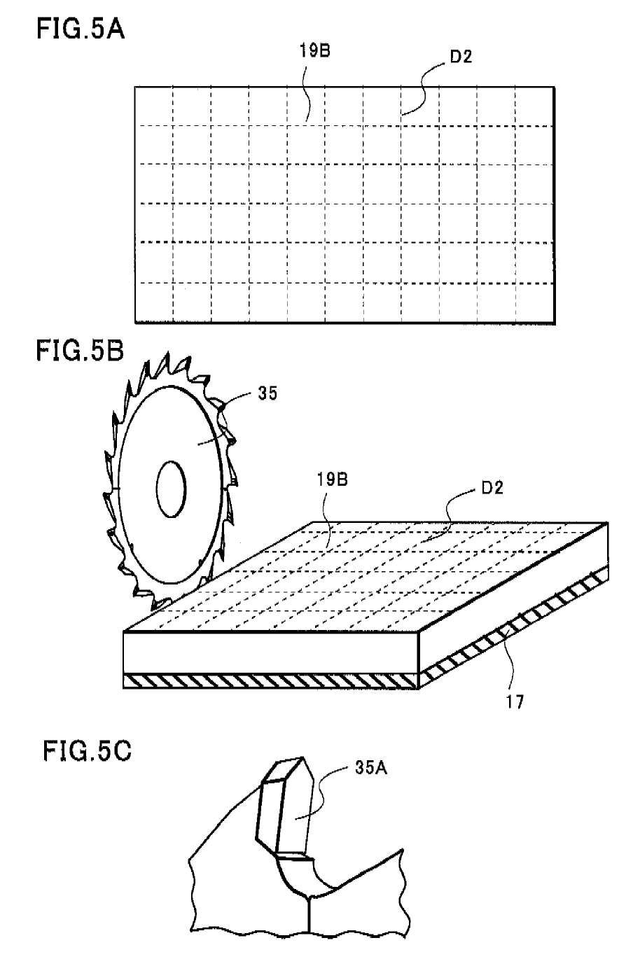

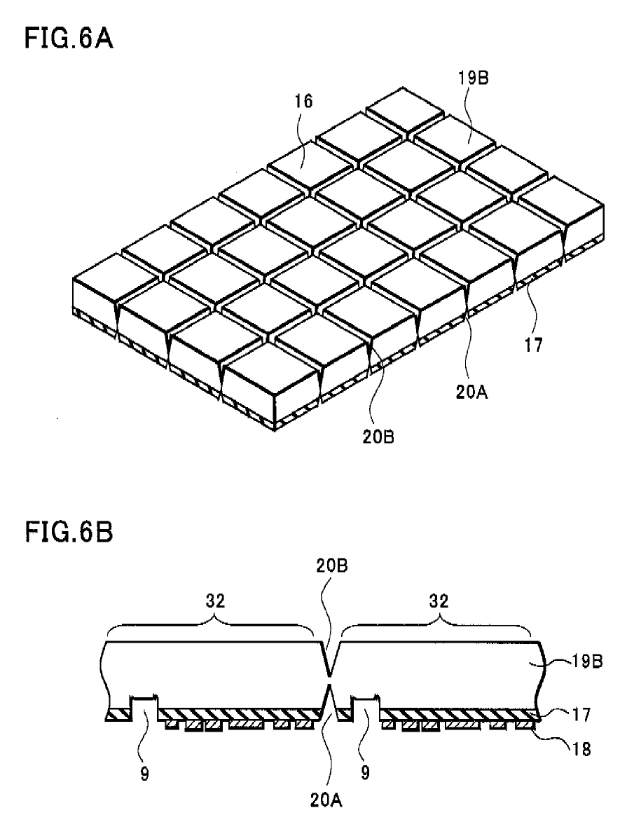

Third process: see FIG. 5A to FIG. 6B

This is a process for forming first grooves 20A and second grooves 20B in lattice shapes onto the surface and the rear surface of the medium-sized metal board 19B. FIG. 5A is a plan view showing the medium-sized metal board 19B divided in the earlier process. FIG. 5B is a perspective view showing a state of forming the grooves on the metal board 19B by use of a V cutting saw 35. FIG. 5C is an enlarged view of a blade 35A.

As shown in FIG. 5A and FIG. 5B, the first grooves 20A and the second grooves 20B are formed on the surface and the rear surface of the metal board along dicing lines D2 by the V cutting saw 35 rotating at high speed. The dicing lines D2 are formed into lattice shapes. Moreover, the dicing lines D2 correspond to boundaries of the respective units 32 formed on the insulating layer 17.

The shape of the V cutting saw 35 will be described with reference to FIG. 5C. The V cutting saw 35 includes multiple blades 35A having the shape as shown in the drawing. Here, the shape of the blade 35A corresponds to the shape of the grooves to be formed on the metal board 19B. To be more precise, the V-shaped grooves are formed by use of the V cutting saw 35 having the V-shaped blades 35A.

Next, the shape of the metal board 19B after forming the grooves 20 will be described with reference to FIG. 6A and FIG. 6B. FIG. 6A is a perspective view of the metal board 19B on which the grooves are formed by use of the cutting saw 31, and FIG. 6B is a cross-sectional view of the metal board 19B.

As shown in FIG. 6A, the first grooves 20A and the second grooves 20B are formed in the lattice shapes on the surface and the rear surface of the metal board 19B. Here, the two-dimensional positions of the first grooves 20A and the second grooves 20B correspond to one another. In this embodiment, since the grooves are formed by use of the V cutting saw 35 having the V-shaped blades 35A, the grooves 20 have cross sections in V shapes. Meanwhile, centerlines of the grooves 20 correspond to the boundaries of the respective units 32 formed on the insulating layer 17. Here, the first grooves 20A are formed on the surface where the insulating layer 17 is formed, and the second grooves 20B are formed on the opposite surface.

The shape and other features of the grooves 20 will be described with reference to FIG. 6B. Here, the grooves 20 are formed into the cross sections of substantially V shapes. Moreover, the depths of the first grooves 20A and the second grooves 20B are shallower than a half of the thickness of the metal board 19B. Therefore, the respective units 32 are not divided into the individual circuit boards 16 in this process. That is, the respective units 32 are connected to one another by the remaining thickness of the metal board 19B corresponding to the portions provided with the grooves 20. Accordingly, it is possible to treat the metal board 19B as a single sheet until the metal board 19B is divided into the individual circuit boards 16. Moreover, if the “burr” is generated in this process, the “burr” is removed by performing high pressure cleaning.

Here, the widths and the depths of the first and second grooves 20A and 20B are adjustable. To be more precise, it is possible to increase an effective area capable of forming the conductive patterns 18 by reducing aperture angles of the first grooves 20A. Meanwhile, a similar effect is also achieved by reducing the depths of the first grooves 20A. Moreover, by increasing the aperture angles of the second grooves 20B, it is possible to promote permeation of the resin in the vicinity of the second grooves 20B in a subsequent process.

It is also possible to form the first grooves 20A and the second grooves 20B in the same size. In this way, it is possible to suppress occurrence of warpage of the metal board 19B on which the grooves 20 are formed in the lattice shapes.

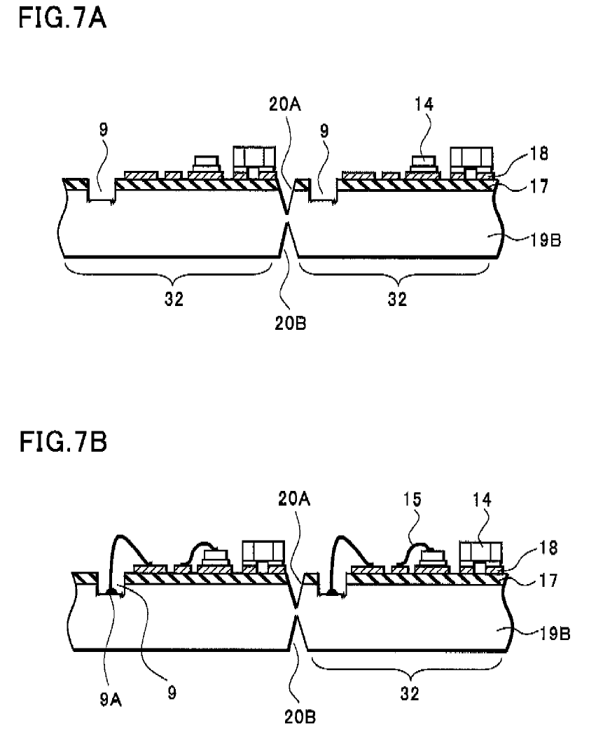

Fourth process: see FIGS. 7A and 7B

This is a process for mounting the circuit elements 14 on the conductive patterns 18 and electrically connecting the circuit elements 14 to the conductive patterns 18.

First, as shown in FIG. 7A, the circuit elements 14 are mounted in given positions on the conductive patterns 18 by use of a solder member such as solder.

Next, as shown in FIG. 7B, the circuit elements 14 are electrically connected to the conductive patterns 18. Here, the respective units 32 in the number of several tens to several hundreds of pieces formed on the single metal board 19B are subjected to wire bonding in a lump. Meanwhile, wire bonding of the circuit elements 14 and the conductive patterns 18 are performed at the same time. In addition, wire bonding of the exposure holes 9 and the conductive patterns 18 are also performed. In this process, the exposure holes 9 are connected to the conductive patterns 18 by use of the thin metallic wires 15, which are similar to the one used in the wire bonding of the circuit elements 14. Accordingly, it is possible to perform all the wire bonding by use of a single bonder (a machine for forming the thin metallic wires). In this way, it is possible to improve productivity. Meanwhile, it is possible to use aluminum as the material for the thin metallic wires 15 for connecting the exposure holes 9 to the conductive patterns 18, which is the similar material as the metal board 19B. In this way, it is possible to perform the wire bonding without forming a plated film at the bottom portions of the exposure holes 9.

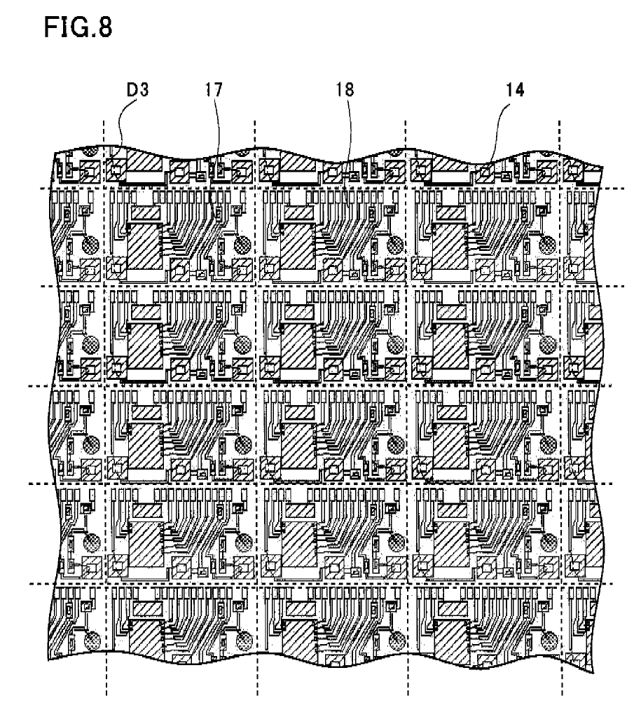

The hybrid integrated circuits in the respective units 32 formed on the metal board 19B will be described with reference to FIG. 8. FIG. 8 is a plan view of a part of the hybrid integrated circuits 17 formed on the metal board 19B. In reality, more numerous units of the hybrid integrated circuits 17 are formed thereon. Moreover, dicing lines D3 for dividing the metal board 19B into the individual circuit boards 16 are indicated by dashed lines in the drawing. As it is apparent from the drawing, the conductive patterns 18 constituting the individual hybrid integrated circuits 17 are located very close to the dicing lines D3. From this point, it is apparent that the conductive patterns 18 are formed thoroughly on the surface of the metal board 19B.

In the foregoing explanation, the hybrid integrated circuits are formed in a lump on the surface of the board 19B having the rectangular shape. Here, when there is a restriction in a manufacturing machine for performing die bonding or wire bonding, it is also possible to divide the metal board 19B into desired shaped prior to this process.

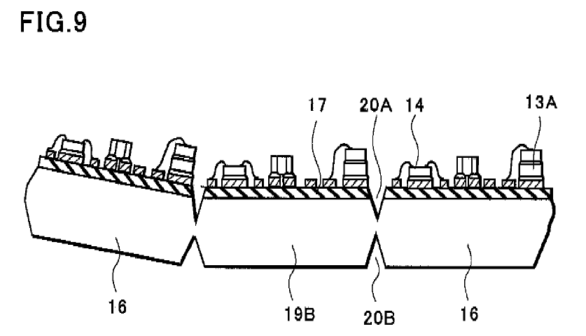

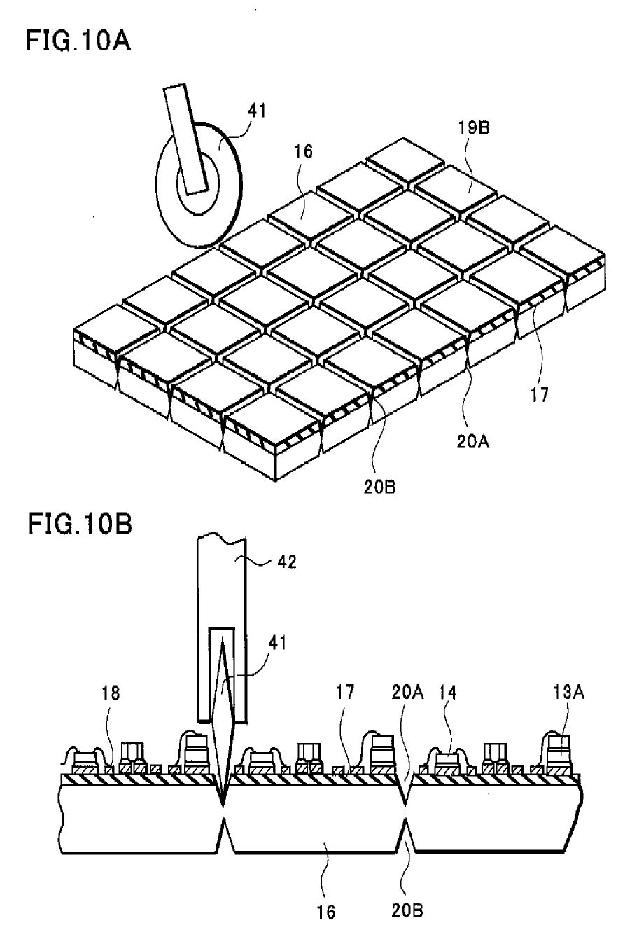

Fifth process: see FIG. 9 to FIG. 10B

This is a process for separating the circuit boards 16, which are the respective units, by means of dividing the metal board 19B into pieces along the lines where the grooves 20 are formed. FIG. 9 is a cross-sectional view showing a method of separating the respective circuit boards 16 by bending the metal board 19B. Meanwhile, FIG. 10A is a perspective view showing a state of dividing the metal board 19B into the individual circuit boards 16 by use of a round cutter 41. FIG. 10B is a cross-sectional view relevant to FIG. 10A. Here, although it is not illustrated in the drawing, numeral pieces of the hybrid integrated circuits are formed on the insulating layer 17.

The method of dividing the metal board 19B into the individual circuit boards 16 by bending the metal board 19B will be described with reference to FIG. 9. In this method, the metal board 19B is partially bent so that the positions where the first grooves 20A and the second grooves 20B are formed are folded. The positions where the first grooves 20A and the second grooves 20B are formed are joined together only by the remaining thickness of the metal board 19B where the grooves 20 are not provided. Therefore, it is possible to break such junctions easily by bending the metal board 19B in these positions. When the metal board 19B is the board made of aluminum, the metal board 19B should be bent several times until the circuit boards 16 are separated because aluminum is a viscous metal.

Next, the method of dividing the metal board 19B by use of the round cutter 41 will be described with reference to FIGS. 10A and 10B. As shown in FIG. 10A, the metal board 19B is cut out by pushing along the dicing lines D3 with the round cutter 41. In this way, the metal board 19B is divided into the individual circuit boards 16. The round cutter 41 cuts out by pushing the remaining thickness of the metal board 19B where no grooves 20 are formed, which correspond to the centerlines of the grooves 20.

Details of the round cutter 41 will be described with reference to FIG. 10B. The round cutter 41 has a discoid shape and the periphery thereof is formed into a sharp edge. The center of the round cutter 41 is fixed to a support 42 so that the round cutter 41 can rotate freely. The round cutter 41 does not have driving force. That is, the round cutter 41 is rotated by moving the round cutter 41 along the dicing lines D3 while pressing part of the round cutter 41 against the metal board 19B.

In addition to the method described above, it is also possible to consider a method of separating the individual circuit boards by removing the remaining thickness of the board by use of a laser in the positions provided with the first and second grooves 20A and 20B. Moreover, it is possible to remove the remaining thickness of the board by use of a cutting saw which rotates at high speed. Furthermore, it is also possible to separate the individual circuit boards by stamping.

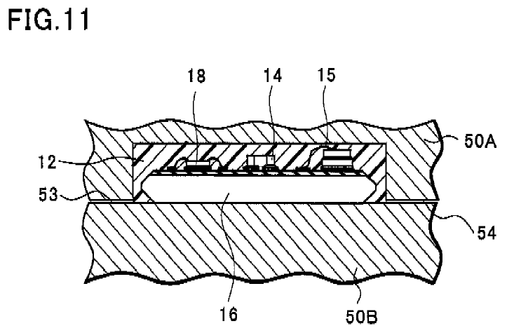

Sixth process: see FIG. 11

A process for sealing the circuit board 16 with the sealing resin 12 will be described with reference to FIG. 11. FIG. 11 is a cross-sectional view showing the process of sealing the circuit board 16 with the sealing resin 12 by use of molds 50.

Firstly, the circuit board 16 is placed on a lower mold 50B to house the circuit board 16 in a cavity formed inside the molds 50. Next, the sealing resin 12 is injected through a gate 53. As the method of sealing, it is possible to adopt either the transfer molding using thermosetting resin or the injection molding using thermoplastic resin. Then, the gas inside the cavity corresponding to the amount of the sealing resin 12 injected through the gate 53 is discharged to outside through an air vent 54.

As described above, inclined portions are provided on side surfaces of the circuit board 16. Accordingly, the sealing resin 12 permeates the inclines portions in the course of sealing with the insulative resin. In this way, an anchor effect is generated between the sealing resin 12 and the inclined portions, and bonding between the sealing resin 12 and the circuit board 16 is thereby strengthened.

After the above-described processes, the circuit board 16 sealed by the resin is finished as a product after a lead cutting process and the like.

1. A hybrid integrated circuit device comprising:
a circuit board made of metal;
an insulating layer covering a surface of the circuit board;
a conductive pattern formed on a surface of the insulating layer;
a circuit element disposed in and electrically connected to a desired position of the conductive pattern;
an exposure hole portion penetrating the insulating layer and exposing the circuit board;
a flat portion formed on a bottom portion of the exposure hole portion; and
a thin metallic wire for electrically connecting the flat portion to the conductive pattern.

2. The hybrid integrated circuit device according to claim 1,
wherein the circuit element is electrically connected to the conductive pattern by use of a thin metallic wire having the same diameter as the thin metallic wire for electrically connecting the flat portion to the conductive pattern.

3. The hybrid integrated circuit device according to claim 1,
wherein the circuit board and the thin metallic wire are made of the metal of the same kind.

4. A method of manufacturing a hybrid integrated circuit device comprising:
providing an insulating layer on a surface of a circuit board made of metal;
forming a conductive pattern on a surface of the insulating layer;
forming an exposure hole portion so as to penetrate the insulating layer and thereby to expose the circuit board from a bottom portion of the exposure hole portion;
forming a flat portion at the bottom portion of the exposure hole portion;
electrically connecting a circuit element to the conductive pattern; and
electrically connecting the flat portion to the conductive pattern by use of a thin metallic wire.

5. A method of manufacturing a hybrid integrated circuit device comprising:
providing an insulating layer on a surface of a circuit board made of metal;
forming conductive patterns on the surface of the insulating layer so as to constitute a plurality of units;
forming exposure hole portions so as to penetrate the insulating layer in the respective units and thereby to expose the circuit board from bottom portions of the exposure hole portions;
forming flat portions at the bottom portions of the exposure hole portions in the respective units;
electrically connecting circuit elements to the conductive patterns in the respective units;
electrically connecting the flat portions to the conductive patterns in the respective units by use of thin metallic wires; and
separating the respective units.

6. The method of manufacturing a hybrid integrated circuit device according to any of claims 4 and 5,
wherein the circuit board is made of metal mainly containing aluminum, and
the bottom portion of the exposure hole portion is formed into a rough surface by forming the exposure hole portion using a drill.

7. The method of manufacturing a hybrid integrated circuit device according to any of claims 4 and 5,
wherein the circuit element is electrically connected to the conductive pattern by use of a thin metallic wire having the same diameter as the thin metallic wire for electrically connecting the flat portion to the conductive pattern.

8. The method of manufacturing a hybrid integrated circuit device according to any of claims 4 and 5,
wherein the same kind of metal as the circuit board is used as a material for the thin metallic wire.

9. The method of manufacturing a hybrid integrated circuit device according to any of claims 4 and 5,
wherein the exposure hole portion is formed by use of a drill having a diameter of at least 1 millimeter.

10. The method of manufacturing a hybrid integrated circuit device according to any of claims 4 and 5,
wherein the flat portion is formed by attaching a flatly formed tip end of an abutting bar onto the bottom portion.
